(19) United States
(12) Patent Application Publication
(10) Pub. No.: US 2002/0070744 A1
(43) Pub. Date: Jun. 13, 2002

(54) Automatic scan pad assignment utilizing I/O pad architecture

(76) Inventor: Scott A. Linn, Corvallis, OR (US)

Correspondence Address: AGILENT TECHNOLOGIES, Legal Department, 51U-PD, Intellectual Property Administration, P.O.Box 58043, Santa Clara, CA, 95052-8043, US

(21) Appl. No.: 09/731,588

(22) Filed: Dec. 7, 2000

(51) Int. Cl. G01R 31/02

(52) U.S. Cl. 324/763

(57) ABSTRACT

Input and output test multiplexers are added to an input/output pad's architecture to switch the pad between a test mode and the normal operating mode. One input multiplexers has inputs coupled to a test input signal and the I/O pad input signal. Another input multiplexer has inputs coupled to an input enable signal and a test input enable signal. An input mode signal is used to switch among these inputs, depending on the mode of the integrated circuit. One output multiplexer has input coupled to a test output signal and an output signal from the integrated circuit core logic function. Another output multiplexer has inputs coupled to an output enable signal and a test output enable signal. An output mode signal is used to switch among these output signals, depending on the mode of the integrated circuit.

### TECHNICAL FIELD

The present invention relates generally to integrated circuits. More particularly, the present invention relates to the testing of integrated circuits.

### BACKGROUND OF THE INVENTION

Historically, most integrated circuit testing was done using in-circuit test equipment. Recent advances in VLSI technology now enable microprocessors and application specific integrated circuits (ASICs) to be packaged into fine pitch, high transistor-count packages. These high-density devices pose unique manufacturing challenges, such as the accessibility of test points and the high cost of testing and test equipment.

Typically, integrated circuit testing is accomplished by using a process referred to as automated test generation scan (ATG) testing. ATG is a methodology where all of the “normal” storage elements (e.g., flip-flops) in a design are connected together in a string and the head/tail connections are taken out to pads so that they can be loaded serially to easily initialize the state of the part. The pad inputs are set up and clocked as if the integrated circuit was operating normally. The states of the internal flip-flops are then scanned back out via a scan-out process and compared to what was expected to determine the state of the integrated circuit.

Another form of testing, used after the integrated circuit is soldered to a board, is referred to as boundary scan testing. This testing allows, via software control, controllability and observability of the boundary pins of a Joint Test Access Group (JTAG) compatible device. FIG. 1 illustrates a typical prior art structure for input and output pins of a JTAG-compliant device.

During standard operations, boundary cells (101 and 102) are inactive and allow data from either the input logic (105) or the output logic (110) to be propagated normally through the device. During a test mode, all input signals are captured by the storage elements (115 and 120) (typically D-type master/slave flip-flops) for analysis and all output signals are preset to test down-string devices. The operation of the scan-in cells (101 and 102) is controlled through a test controller and an instruction register.

Boundary scan testing is accomplished by first grouping the boundary cells of the integrated circuit into a scan chain. The boundary scan test sets up values on the pads of the device under test. A clock is then applied to the integrated circuit, at which point the pad state is captured into the boundary scan chain. The boundary scan chain may then be scanned out to read the captured states of the pads to check for proper response.

The boundary scan test next sets up the testing state on the pad. A clock is then applied to the integrated circuit to clock the state into the flip-flop. The output of the block of the integrated circuit is then checked for the proper response.

Most integrated circuit designers use boundary scan testing where a state is shifted through the boundary chain, which sets up the state of the output pads only (no other internal storage elements are affected). The state of the pads can also be captured by the JTAG boundary register and scanned out the JTAG pins to observer the values being driven on those pins.

The problem with the present state of integrated circuit testing is that the integrated circuit designers have to plan ahead for the testing of the integrated circuit by adding the testing circuitry into the electronic logic function. This takes valuable design time and produces extra delay from the testing logic in some critical paths. Additionally, the present testing architecture and methods limits the number of scan chains that are possible. There is a resulting unforeseen need for a method and apparatus for testing complex integrated circuits in a more economical and rapid fashion without introducing delays in the timing of critical paths.

### SUMMARY OF THE INVENTION

The present invention encompasses an integrated circuit comprised of input/output pads that have an architecture optimized for testing. The integrated circuit logic performs an electronic function that must be tested by the test process of the present invention.

Each input/output pads is coupled to the integrated circuit logic and provides input/output connections for the electronic signals that go to and are generated from the integrated circuit logic while performing the electronic function. The input/output pads are comprised of a multiplexing apparatus that is coupled to a control signal. The control signal switches between a plurality of signals coupled to the multiplexing apparatus.

### BRIEF DESCRIPTION OF THE DRAWINGS

FIG. 1 shows a simplified block diagram of typical prior art boundary scan structure in an integrated circuit.

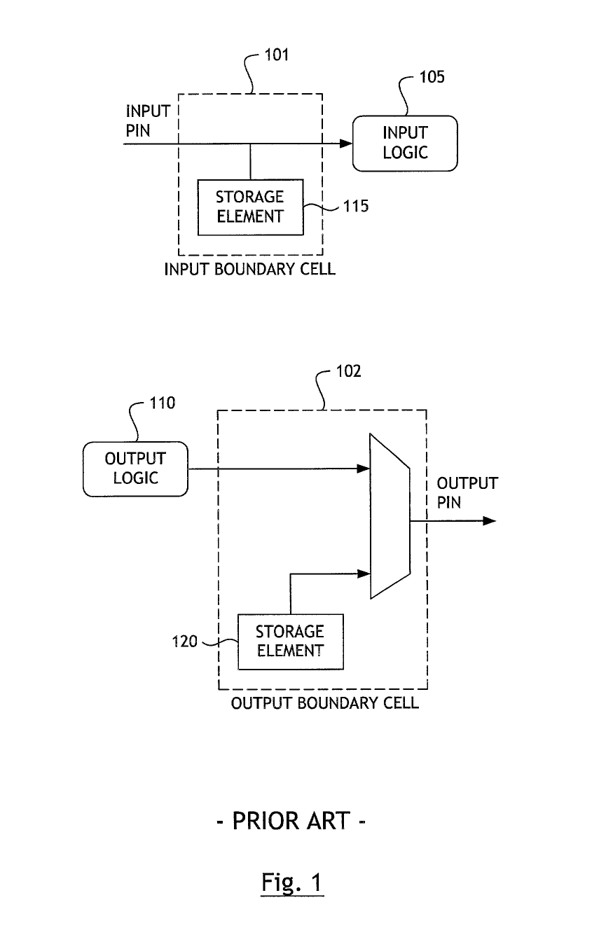

FIG. 2 shows a block diagram of a test pad of the present invention incorporating the multiplexers.

FIG. 3 shows a flowchart of the testing process of the present invention.

FIG. 4 shows an integrated circuit of the present invention in accordance with the test pad of FIG. 2.

### DETAILED DESCRIPTION OF THE PREFERRED EMBODIMENT

The input/output (I/O) pads of the present invention are comprised of multiplexers that enables assignment of a large number of scan chains to reduce testing time by the parallel testing of the scan chains. The I/O pads also provide the ability to define scan chain assignments later in the integrated circuit design process so as not to require a longer integrated circuit design process.

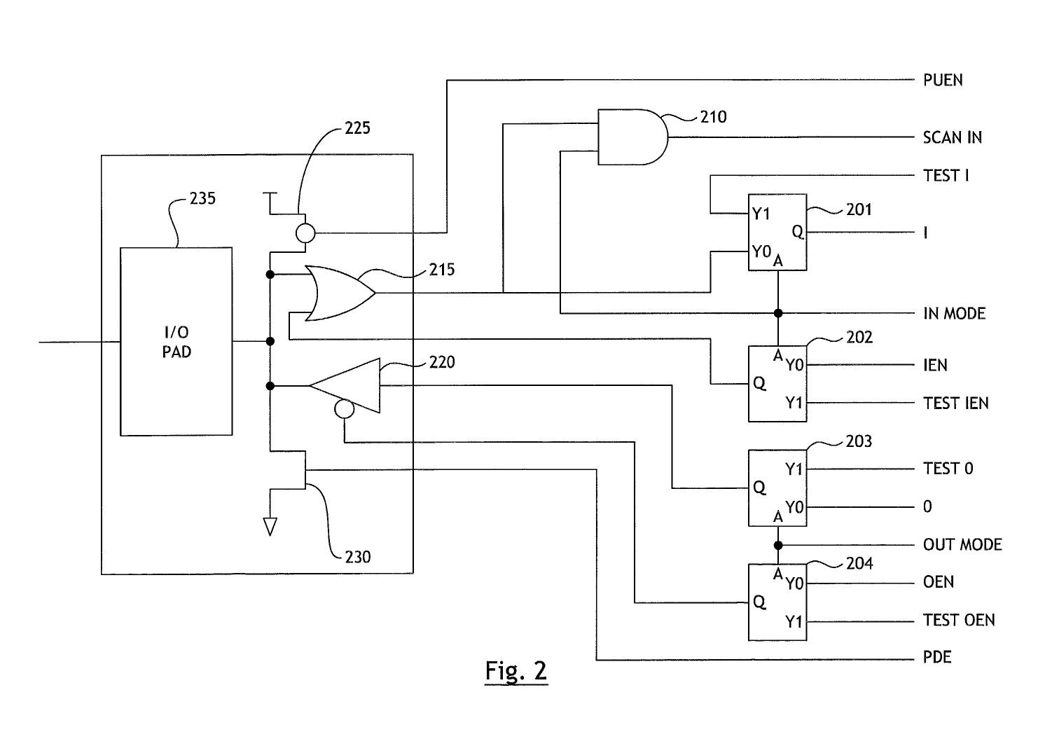

FIG. 2 illustrates a block diagram of the I/O pad of the present invention. In the preferred embodiment, each I/O pad of an integrated circuit is comprised of the logic illustrated in FIG. 2. Alternate embodiments use different circuitry to provide substantially the same results that are provided by the multiplexers and other logic of the present invention. In yet another alternate embodiment, the I/O pad of FIG. 2 is only in a limited number of pads of the integrated circuit while the remaining pads are of conventional design.

While the preferred embodiment of the present invention uses multiplexers to accomplish the switching task, alternate embodiments use other similar devices to accomplish the same task. For example, one embodiment may use switches with control inputs that switch between the input signals.

The I/O pad logic of the present invention is comprised of two multiplexers (201 and 202) for the input test mode and two multiplexers (203 and 204) for the output test mode. Each multiplexer is a dual input multiplexer. The multiplexer's signal inputs are each labeled Y0 and Y1. The control input to select from among the signal inputs is A while the output is labeled Q.

As is well known in the art, when a logic 0 is present on the control signal input, the Y0 input is switched to the Q output. When a logic 1 is present on the control signal input, the Y1 input is switched to the Q output.

In the present invention, the input (201 and 202) and output (203 and 204) multiplexers each have their enable signals tied together. In this case, each Y0 input for the output multiplexers (203 and 204) is switched to the output of its respective multiplexer when the select signal is a logic 0. Additionally, each Y1 input for the output multiplexers (203 and 204) is switched to the output of its respective multiplexer when the select signal is a logic 1. The same is true for the input multiplexers (201 and 202).

The input multiplexers of the present invention are further divided up into an input signal multiplexer (201) and an input signal enable multiplexer (202). The input signal multiplexer (201) has the test input signal (TEST I) coupled to the Y1 input and the input from the I/O pad (235) coupled to the Y0 input. The I/O pad input is coupled through some additional logic that is discussed subsequently. The output of the input signal multiplexer (201) is the signal (I) that goes to the integrated circuit core to interact with the integrated circuit function.

The test input signal (TEST I) is the test value that is input to the pad. This value is used to bypass the input data path when the present invention is in the test scan mode. The preferred embodiment of the process of the present invention requires all I/O pads to be outputs in the scan mode to avoid scan-test timing problems during “at-speed” scan testing. The “at-speed” scan testing is a methodology where the state is scanned into the part, the part is clocked twice at its rated frequency, and the state is scanned back out. At this point, all of the I/O pads now must be inputs for at least two reasons.

First, the test equipment often has a larger capacitive loading than a product, thus slowing the outputs. Second, many of the pads are both input and output so that the data will be slowly driven out, then wrapped back in through the input path. This will most probably violate timing. The pads are restricted to being inputs only to avoid the output related delay violations.

The input signal enable multiplexer (202) has an input enable signal (IEN) as the input that is coupled to the Y0 input and the test input enable signal (TEST IEN) is coupled to the Y1 input of the multiplexer (202). The output of this multiplexer (202) is coupled to the input of a logic OR gate (215). The other input of the OR gate (215) is coupled to the I/O pad (235) that receives the external input signal. The I/O pad (235) is the location where the bond wires to the core integrated circuit and integrated circuit package pins are connected.

The input enable signal (IEN) is a normal pad signal that is used to select the input signal from the I/O pad (235). The input enable signal (IEN) allows the output of the OR gate (215) to change, thus allowing the I/O pad (235) input signal through, when active low. If input enable signal (IEN) is high, the output of the OR gate (215) will be high no matter what the state of the I/O pad (235) input signal. If a pad incorporating the multiplexers of the present invention is used for output only, the input enable signal (IEN) would be tied high to prevent the input signal (I) from changing.

The test input enable signal (TEST IEN) has a similar function to the input enable signal (IEN). The test input enable signal (TEST IEN) is used during the test mode to enable the test signal that is applied to the other input of the OR gate (215). This signal is active low and, in the preferred embodiment, is tied low. Therefore, whenever the input signal enable multiplexer (202) selects the test input enable signal (TEST IEN), the enable input of the OR gate (215) will be tied low to allow the test value to propagate through.

The multiplexer control input of the input multiplexers (201 and 202) are coupled to an input mode control signal (IN MODE). This signal determines how an I/O pad (235) changes function during the test mode. This signal is used whether or not the particular pad is used for a scan-in test or scan-out test during the test mode.

In a similar fashion, the output multiplexers (203 and 204) of FIG. 2 are further divided into an output signal multiplexer (203) and an output signal enable multiplexer (204). The Y0 input of the output signal multiplexer (203) is coupled to the output signal (O) that the integrated circuit core is trying to drive to the I/O pad (235). If the buffer (220) that is coupled to the output of the multiplexer (203) is in the low impedance mode, the output signal (O) will be coupled to the I/O pad (235) and from there to the outside world. The control signal of the buffer (220) will be discussed subsequently.

The Y1 input of the output signal multiplexer (203) is coupled to a test output signal (TEST O). This signal is the test version of the output signal (O). If the I/O pad (235) is being used in the test mode, then the scan output will be coupled to the test output signal (TEST O).

The output signal enable multiplexer (204) controls the high impedance mode of the buffer (220). The output of the multiplexer (204) is coupled to the buffer control input that is active low. Therefore, whenever the output of the output signal enable multiplexer (204) is low, the buffer (220) is in a low impedance mode and the signal at the input of the buffer is allowed to propagate through the buffer (220). If the control input is high, the buffer (220) output is in the high impedance state and it is removed from the I/O pad (235).

The Y0 input of the output signal enable multiplexer (204) is coupled to an output enable signal (OEN). The output enable signal (OEN) determines the pad direction in the normal mode (input or output). This signal is active low.

The Y1 input of the output signal enable multiplexer (204) is coupled to a test output enable signal (TEST OEN). The test output enable signal (TEST OEN) is the test mode equivalent of the output enable signal (OEN). This signal is also active low.

The control input for the output multiplexers (203 and 204) is coupled to an output mode signal (OUT MODE). This signal (OUT MODE) determines which values control the output path in the test mode. The output path can be controlled by either a combination of O/OEN or TEST O/TEST OEN depending on the state of the output mode signal (OUT MODE).

In the preferred embodiment, two transistors (225 and 230) are used as pull-up/pull-down devices. These transistors (225 and 230) provide a solid logic 1 or 0 level when nothing is driving the pad. In an alternate embodiment, pull-up/pull-down resistors are used in place of the transistors. These transistors (225 and 230) are enabled by their respective pull-up (PUEN) and pull-down (PDE) signals. The pull-up signal (PUEN) is active low while the pull-down signal (PDE) is active high.

The PUEN and PDE signals are generated by the integrated circuit core and are design-dependent. Some designs might tie these inputs to be always off, one to be always on, or turn them on/off under certain circumstances. If a user is using JTAG, then JTAG will also need to control these signals during JTAG mode to verify operation. In one embodiment, a multiplexer is used in the core that selects between normal mode and JTAG mode. Most pad instantiations in a design do not use weak pulls. Pads that most often have these are resets and mode select inputs.

When the I/O pad (235) of FIG. 2 is operating in the scan-in test mode, a scan-in test status signal (SCAN IN) is generated by logically AND'ing (210) the IN MODE signal with the output of the OR gate (215). When the IN MODE signal is a logical high it selects the Y1 inputs of the input multiplexers (201 and 202) that, in the preferred embodiment, has a logical low applied. Therefore, the OR gate (215) is set to output whatever is on the I/O pad (235). This signal is input to the AND gate (210) along with the IN MODE signal. The AND gate (210) also keeps the scan-in test status signal from toggling, and therefore drawing excessive power, during the normal mode of integrated circuit operation.

The scan-in test status signal is input to the integrated circuit core. This signal informs the electronic function being performed by the core that the integrated circuit is in the scan test mode and not the normal mode.

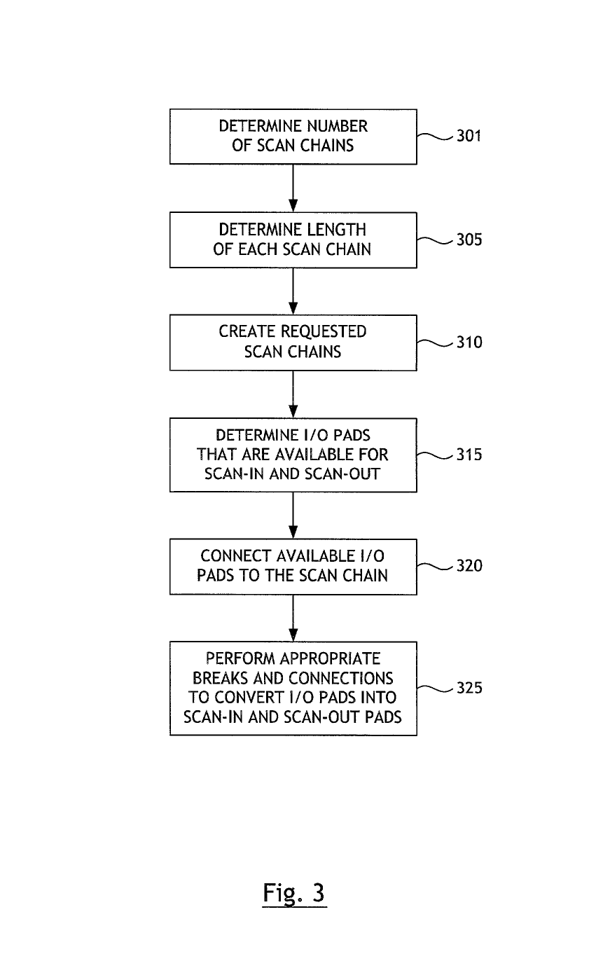

FIG. 3 illustrates a flowchart of the scan-in test process of the present invention. The number of scan chains desired is determined (step 301). The choosing of the number of flip-lops in a scan chain is done by dividing the number of flip-flops in a design by the number of input/output pins available. For example, if a design has 15,000 flip-flops and 200 signal pins of which 190 can be used (10 signal pins being resets, mode inputs, and clocks), then the length of the scan chain will be 15,000/(190/2) or 158 flip-flops. In the preferred embodiment, a scan chain is in the range of 200 to 500 flip-flops. The number of flip-flops in a chain is kept to a minimum for a number of reasons.

First, the more flip-flops in a scan chain, the longer it takes to load them serially and, therefore, the longer the test time. A longer test time costs more to run. However, the more scan chains there are, the more scan-in and scan-out pads are required to load them. The present invention enables the use of more pads for scan-in/out as possible.

A second reason to reduce the number of flip-flops in a scan chain is due to tester memory size. When a scan test is generated that has 15,000 flip-flops in a design and a single scan chain, then 600*15,000 vectors are required (assuming 600 test vectors as typical). This would go beyond the memory of most testers. However, with 50 scan chains, this number is reduced to 50 to 180 k test vectors.

The number of flip-flops present in the integrated circuit design is then divided by the number of scan chains (step 305) in order to determine the length of each scan chain. Based on the flip-flop placement in the integrated circuit die, a scan stitching tool connects the flip-flops to create the requested scan chains (step 310).

The scan stitching tool is a computer controlled testing device that uses the layout data from the router tool to determine placement of all of the storage elements (flip-flops) in a design. The tool then uses this information to wire them up serially with the shortest wiring path (not to minimize routing time but to minimize wire area and make the integrated circuit operate faster in scan mode due to shorter wires). When a scan chain is filled, the tool breaks the chain, gets the next flip-flop, and starts building another chain with the shortest path. This continues until all of the flip-flops are used up. This tool is well known in the art of integrated circuit testing and is not discussed further.

The I/O pads that are available to be used for both scan-in and scan-out functionality are determined (step 315). These pads are determined on a placement basis. In other words, sometimes an integrated circuit has large interior blockages to wiring in the form of IP blocks (e.g., RAM, ROM, CPU, and other hard macros). Sometimes these allow wire routing over them. If some of the integrated circuit pads have large blockages to routing for a long distance, it is difficult to get wires to them. The scan multiplex pads of the present invention require a large number of wires, so this would make these types of pads undesirable. They could be dropped from the list of available scan pads so that the router would have a less difficult time of routing to them.

Another example of how placement comes into effect would be when the integrated circuit is fairly large and, for example, has only two scan chains. This is assuming that the scan stitching tool has the flip-flop at the head of the first scan chain in the upper left corner and the last flip-flop in the first chain has ended up in the middle of the right side. It would make sense, based on this placement, for the tool to choose a pad in the upper left corner to be the scan-in pad and a pad in the middle of the right side to be a scan-out pad. This would minimize the wiring needed to get to the chain. If the scan-in pad was randomly chosen to be in the lower right corner, then the router would have to wire from the lower right corner to the first flip-flop that is in the upper left corner. This is inefficient and slow.

Therefore, it is better to have a tool that looks at the scan stitched output, sees where the various heads and tails of the scan chains are placed inside the die, and intelligently assign the available pads to be scan-ins and scan-outs. This would be based on where they are located.

The available scan-in and scan-out I/O pads are connected to the beginning and end of the above determined stitched scan chain (step 320). Also at this time, the scan stitching tool performs the appropriate breaks and connects to convert the I/O pads into scan-in and scan-out pads respectively (step 325).

The connections performed in step 325 are described as follows: the integrated circuit core O and OEN signals are connected to the Joint Test Access Group (JTAG) boundary cell. The JTAG boundary cell outputs that are normally routed to the pad's output (O) during the normal mode are coupled to the TEST O signal. The JTAG boundary cell outputs that are normally routed to the pad's OEN go to the TEST OEN during the test mode. A JTAG mode signal must be logically OR'd with any existing signal driving the OUT MODE signal.

For the input signals, a read-only JTAG input cell can be connected to either the pad I or SCAN IN signals. If the input signal is connected to the SCAN IN signal, a JTAG mode signal must be logically OR'd with any existing signal driving the IN MODE signal.

A JTAG input cell that is non-read only is coupled to its pad input to SCAN IN and its output that normally drives to the core connects to the TEST I signal. Additionally, a JTAG mode signal must be logically OR'd with any existing signal driving the IN MODE signal.

In the preferred embodiment of the above described process, the scan-in and scan-out assignments are done manually. The selected I/O pads are entered into a text file and the connections are then made by the scan stitching tool. In an alternate embodiment, the scan stitching tool determines the various scan chains, connects them, and automatically assigns pads to be scan-in and scan-out without the manually generated text file.

In order to manipulate the multiplexers of the I/O pads of the present invention, the integrated circuit designer makes a default hook-up that makes any pads available for the scan tool. In the preferred embodiment, SCAN IN is connected to TEST I, IN MODE is connected to the core signals (ATG TEST MODE & (SPE|˜SPD)), OUT MODE is connected to (ATG TEST MODE & (SPE|SPD)), TEST IEN is tied low, and TEST O/TEST OEN is tied high.

If a pad is chosen to be a scan-in pad, then the tool would connect the pad's SCAN IN port to the head of the scan chain. If the pad is chosen to be a scan-out pad, then the tool connects the tail of a scan chain to TEST O. TEST OEN would change from a “1” to ˜SPE (an internal chip signal). TEST IEN changes from a “0” to a “1”. While the test multiplexers require a number of default connections to be made by the integrated circuit designer, they are the same for almost all of the pads (except CLK, Modes, Resets, and scan control signals).

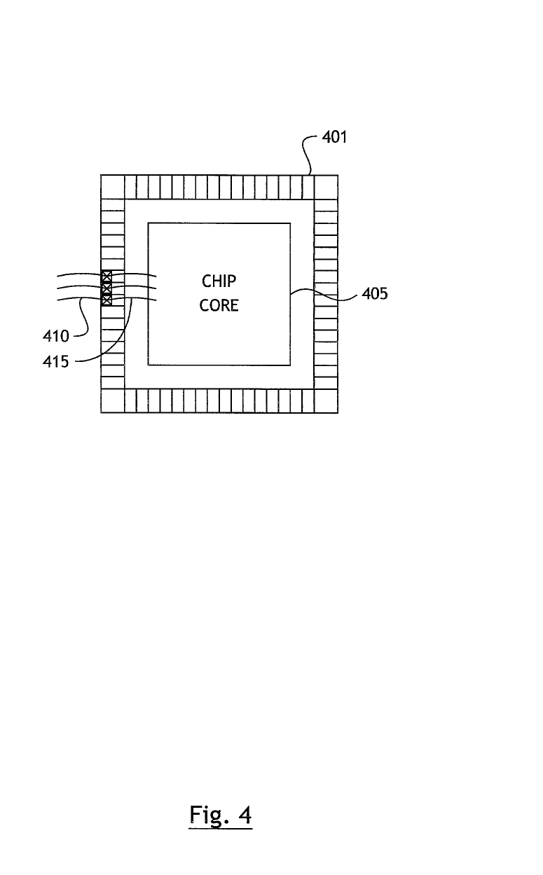

FIG. 4 illustrates the I/O pad architecture of the present invention incorporated into an integrated circuit design. The pad ring (401) surrounds the integrated circuit core (405). The pad ring (401) is comprised of a large number of I/O pads in accordance with FIG. 2. The quantity of pads in the pad ring (401) is determined by the integrated circuit complexity and the quantity of inputs and outputs required by the integrated circuit function.

The bond wires (415) from the integrated circuit core (405) are wired from the core function (405) to each appropriate pad on the pad ring (401). There are also bond wires (410) from the pad ring to the individual pins of the integrated circuit package (not shown). The bonding of these wires and the integrated circuit structure are well known in the art and not discussed further.

In summary, the I/O pad architecture of the present invention provides many benefits over the prior art. For a scan-only integrated circuit, the advantage is that the scan-in/scan-out pad identification work can be left to the back-end of the chip design so that the designer does not have to worry about it. Timing is not affected when scan pads are defined and the integrated circuit vendor can minimize test time by using a large number of scan pads, whereas the designer would not want to be bothered by that much work.

For an integrated circuit with JTAG only, the I/O pad architecture of the present invention are useful in that JTAG can be inserted without affecting the critical path timing for normal integrated circuit mission mode. The JTAG boundary scan insertion is often done by a vendor tool, but must be verified by the customer later.

For an integrated circuit with both scan and JTAG, scan and JTAG functionality both use the test mode path of the multiplexed pads to achieve the above described benefits. All of these benefits save time and money for the integrated circuit designer.

Numerous modifications and variations of the present invention are possible in light of the above teachings. It is therefore to be understood that within the scope of the appended claims, the invention may be practiced otherwise than as specifically described herein.

What is claimed is:

1. An integrated circuit having an input/output pad architecture optimized for testing, the integrated circuit comprising:
integrated logic that performs an electronic function; and
a plurality of input/output pads, coupled to the integrated logic, that provide input/output connections for electronic signals going to and generated from the integrated logic performing the electronic function, at least one of the input/output pads comprising a multiplexing apparatus coupled to a control signal that switches between a plurality of signals coupled to the multiplexing apparatus.

2. The integrated circuit of claim 1 wherein the multiplexing apparatus comprises a multiplexer having at least one control input coupled to the control signal for selecting a first signal from a plurality of input signals to be allowed to exit an output of the multiplexer.

3. The integrated circuit of claim 1 wherein the multiplexing apparatus comprises a switch having control inputs coupled to the control signal for selecting a first input signal from a plurality of signal inputs to be allowed to exit an output of the switch.

4. The integrated circuit of claim 1 and further comprising interface logic for coupling the multiplexing apparatus to the input/output pad, the interface logic having the ability to select between a test mode and a normal mode in response to the control signal.

5. The integrated circuit of claim 1 wherein the control signal is a test enable signal that switches the plurality of input/output pads between a normal mode and a test mode.

6. An integrated circuit having an input/output pad testing architecture that provides a test mode function and a normal mode function, the integrated circuit comprising:
integrated logic that performs an electronic function; and
a plurality of input/output pads coupled to the integrated logic, the input/output pads comprising a test mode input/output path for test signals going to and generated from the integrated logic performing the electronic function, the test mode input/output path comprising:
a plurality of input multiplexers coupled to an input control signal that determines the function of the plurality of input multiplexers; and
a plurality of output multiplexers coupled to an output control signal that determines the function of the plurality of output multiplexers.

7. The integrated circuit of claim 6 wherein the plurality of input multiplexers comprises two input multiplexers each having two inputs, an output, and a control input coupled to the input control signal.

8. The integrated circuit of claim 7 wherein the plurality of output multiplexers comprises two output multiplexers each having two inputs, an output, and a control input coupled to the output control signal.

9. The integrated circuit of claim 7 wherein the input control signal selects between a test input value and an input from a pad coupled to a first of the two input multiplexers, the input control signal additionally selecting between an input enable signal and a test input enable signal on a second of the two input multiplexers.

10. The integrated circuit of claim 8 wherein the output control signal selects between an output signal and a test output signal on a first of the two output multiplexers, the output control signal additionally selecting between an output enable signal and a test output enable signal on the second of the two output multiplexers.

11. An integrated circuit having an input/output pad testing architecture to provide test functionality without affecting a normal mode path, the integrated circuit comprising:
integrated logic for performing an electronic function; and
a plurality of input/output pads coupled to the integrated logic, the input/output pads comprising testing architecture having a test function and a normal mode function, the testing architecture comprising:
a first and a second input multiplexer, the first multiplexer having a first input coupled to a test value to be input to the electronic function and a second input coupled to an electronic function input signal, the second multiplexer having a first input coupled to a test enable signal and a second input coupled to an enable signal for the electronic function input signal, the selection of signals to output from the first and second input multiplexers being in response to a first mode control signal; and
a first and a second output multiplexer, the first multiplexer having a first input coupled to an electronic function output signal and a second input coupled to a test output signal, the second multiplexer having a first input coupled to a test output enable signal and a second input coupled to an output enable signal for the electronic function output signal, the selection of signals to output from the first and second output multiplexers being in response to a second mode control signal.

12. The integrated circuit of claim 11 wherein the electronic function input signal is logically OR'd with one of the input enable signal or the test enable signal, the selection of the input enable signal or the test enable signal being in response to the first mode control signal.

13. The integrated circuit of claim 11 wherein one of either the electronic function output signal or the test output signal, in response to the second mode control signal, is coupled to a buffer having a high impedance mode that is controlled by a high impedance mode control input.

14. The integrated circuit of claim 13 wherein the high impedance mode control input is coupled to, in response to the second mode control signal, one of either the test output enable signal or the output enable signal for the electronic function output signal.

15. The integrated circuit of claim 13 wherein an output of the buffer is coupled to an input/output pad of the plurality of input/output pads.

16. The integrated circuit of claim 11 and further including an apparatus to generate a test mode indication signal from the logical combination of the test value and the first mode control signal.

17. A method for testing an integrated circuit comprising a plurality of input/output pads having a test mode function and a normal mode function, the method comprising the steps of:
an input mode control signal selecting between inputs of an input multiplexer, a first multiplexer input coupled to a test value and a second multiplexer input coupled to an electronic function input signal from an input/output pad; and
an output mode control signal selecting between inputs of an output multiplexer, a first multiplexer input coupled to an output test signal and a second multiplexer input coupled to an electronic function output signal.

18. The method of claim 17 and further comprising the step of the input mode control signal selecting between a test mode input enable signal, coupled to a first input of an input test enable multiplexer, and an enable signal for the electronic function input signal coupled to a second input of the input test enable multiplexer.

19. The method of claim 17 and further comprising the step of the output mode control signal selecting between a test mode output enable signal, coupled to a first input of an output test enable multiplexer, and an enable signal for the electronic function output signal coupled to a second input of the output test enable multiplexer.

20. The method of claim 17 and further including the step of generating a test mode indication signal from the logical combination of the test value and the input mode control signal.
